(19) United States
(12) Patent Application Publication
(10) Pub. No.: US 2018/0122583 A1
(43) Pub. Date: May 3, 2018

(54) PHOTOELECTRIC DEVICE USING VALLEY-SPIN PHOTOELECTRON

(71) Applicant: Industry-Academic Cooperation Foundation, Yonsei University, Seoul (KR)

(72) Inventors: HyunYong CHOI, Seoul (KR); SangWan SIM, Seoul (KR); SoonYoung CHA, Seoul (KR); DoEon LEE, Daegu (KR)

(73) Assignee: Industry-Academic Cooperation Foundation, Yonsei University, Seoul (KR)

(21) Appl. No.: 15/637,332

(22) Filed: Jun. 29, 2017

(30) Foreign Application Priority Data
Oct. 28, 2016 (KR) 10-2016-0142224
Apr. 3, 2017 (KR) 10-2017-0043182

(51) Int. Cl. H01G 9/20; H01L 31/032; H01L 31/0352; H01L 31/109; H01L 51/42

(52) U.S. Cl. CPC H01G 9/20; H01L 31/032; H01L 31/035272; H01L 51/441; H01L 51/4213; H01G 9/2009; H01L 31/109

(57) ABSTRACT

Provided is a photoelectric device including a receiving part, a detecting part, and a connecting part. The receiving part may include a transition metal dichalcogenide layer and a charge inducing layer covering the transition metal dichalcogenide layer, and the detecting part may include a topological insulating layer spaced apart from the transition metal dichalcogenide layer. The connecting part may be provided to connect the transition metal dichalcogenide layer to the topological insulating layer.

### CROSS-REFERENCE TO RELATED APPLICATIONS

This U.S. non-provisional patent application claims priority under 35 U.S.C. § 119 to Korean Patent Application No. 10-2016-0142224 and No. 10-2017-0043182, filed on Oct. 28, 2016 and Apr. 3, 2017, respectively, in the Korean Intellectual Property Office, the entire contents of which are hereby incorporated by reference.

### BACKGROUND OF THE INVENTION

The present disclosure relates to a photoelectric device, and in particular, to a photoelectric device using a valley-spin photoelectron.

In a conventional electronic system, data are stored and processed in the form of electric charges. To increase a degree of freedom of the conventional electronic system, various technologies have been developed to exploit the spin, or quantum state, of an electron. For example, there are a spintronics exploiting information on a spin state of an electron and a valleytronics exploiting information on a valley position of an electron in the momentum space.

Although each of the spin information and the valley information is a unit to express a degree of freedom in each field, there is no way to convert or transfer two pieces of information in the two fields. This leads to a difficulty in integrating and exploiting the spintronics and the valleytronics.

### SUMMARY

Some embodiments of the inventive concept provide a photoelectric device, which is configured to produce an electric signal whose direction is changed depending on the kind of a circularly polarized light to be incident thereto.

According to some embodiments of the inventive concept, a photoelectric device may include a receiving part including a transition metal dichalcogenide layer and a charge inducing layer, the charge inducing layer covering the transition metal dichalcogenide layer, a detecting part including a topological insulating layer spaced apart from the transition metal dichalcogenide layer, and a connecting part connecting the transition metal dichalcogenide layer to the topological insulating layer.

In some embodiments, the detecting part may further include first and second detection electrodes provided on the topological insulating layer.

In some embodiments, the transition metal dichalcogenide layer and the topological insulating layer may be spaced apart from each other in a first direction, and the first and second detection electrodes may be spaced apart from each other in a second direction intersecting the first direction.

In some embodiments, the connecting part may include two portions, one of which is provided on a top surface of the transition metal dichalcogenide layer, and another of which is provided on a top surface of the topological insulating layer.

In some embodiments, the connecting part may include graphene, a carbon nanotube, or a silicon membrane.

In some embodiments, the charge inducing layer may be provided in the form of ionic gel.

In some embodiments, the photoelectric device may further include a charge inducing electrode electrically connected to the charge inducing layer.

In some embodiments, the transition metal dichalcogenide layer may include transition metal dichalcogenide, and the topological insulating layer may include a topological insulator.

According to some embodiments of the inventive concept, a photoelectric device may include a transition metal dichalcogenide layer, a charge inducing layer configured to apply an electric field to an upper region of the transition metal dichalcogenide layer, a topological insulating layer spaced apart from the transition metal dichalcogenide layer, and a connecting part connecting the transition metal dichalcogenide layer to the topological insulating layer.

In some embodiments, the photoelectric device may further include a charge inducing electrode electrically connected to the charge inducing layer. The electric field may be applied to the upper region of the transition metal dichalcogenide layer by applying a voltage to the charge inducing electrode.

In some embodiments, a valley-spin photoelectron may be produced in the upper region of the transition metal dichalcogenide layer, when the electric field is applied to the upper region of the transition metal dichalcogenide layer and a circularly polarized light is incident into the transition metal dichalcogenide layer.

In some embodiments, a valley state and a spin state of the valley-spin photoelectron may be coupled to each other.

In some embodiments, the valley-spin photoelectron may have a first spin direction, when the circularly polarized light is a left-handed circularly polarized light, and a second spin direction, when the circularly polarized light is a right-handed circularly polarized light. The first spin direction and the second spin direction may be opposite to each other.

In some embodiments, the valley-spin photoelectron may be transported to a top surface of the topological insulating layer through the connecting part. On the top surface of the topological insulating layer, the valley-spin photoelectron with the first spin direction may be transported in a direction opposite to that of the valley-spin photoelectron with the second spin direction.

In some embodiments, the topological insulating layer may be spaced apart from the transition metal dichalcogenide layer in a first direction. The circularly polarized light may be incident in a direction that is substantially parallel to the first direction, when viewed in a plan view. Here, the first spin direction may be substantially parallel to the first direction, and the second spin direction may be substantially antiparallel to the first direction.

In some embodiments, the photoelectric device may further include first and second detection electrodes that are provided on a top surface of the topological insulating layer. The first and second detection electrodes may be spaced apart from each other in a second direction intersecting the first direction. The valley-spin photoelectron may be transported to the top surface of the topological insulating layer through the connecting part. On the top surface of the topological insulating layer, the valley-spin photoelectron with the first spin direction may be transported toward the first detection electrode, and the valley-spin photoelectron with the second spin direction may be transported toward the second detection electrode.

In some embodiments, the electric field may be used to form a two-dimensional electron gas in the upper region of the transition metal dichalcogenide layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a perspective view illustrating a photoelectric device according to some embodiments of the inventive concept.

FIGS. 2A to 2C are perspective views illustrating an operation of a photoelectric device according to some embodiments of the inventive concept.

FIGS. 3A to 3C are perspective views illustrating an operation of a photoelectric device according to some embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concept will now be described more fully with reference to the accompanying drawings, in which example embodiments are shown. Example embodiments of the inventive concept may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concept are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concept should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments of the inventive concept belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, physical phenomena associated with a topological insulator and a transition metal dichalcogenide material will be explained on the basis of current understanding, but the inventive concept is not limited thereto.

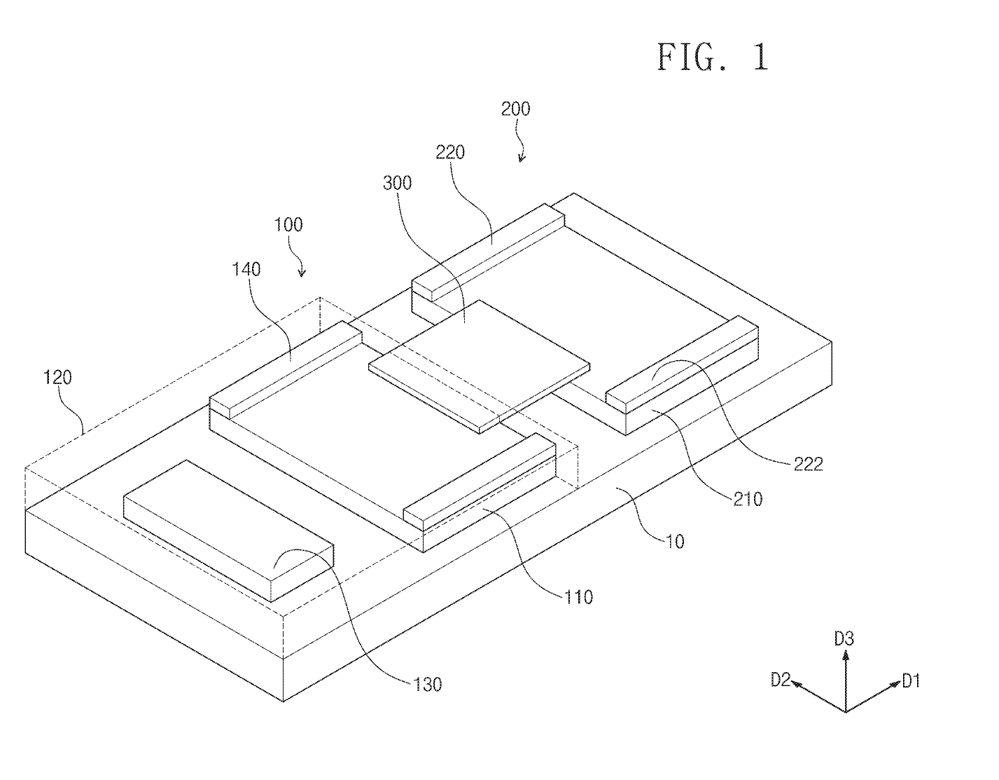

FIG. 1 is a perspective view illustrating a photoelectric device according to some embodiments of the inventive concept.

Referring to FIG. 1, a photoelectric device, according to some embodiments of the inventive concept, may include a receiving part 100, a detecting part 200, and a connecting part 300. The receiving part 100, the detecting part 200, and the connecting part 300 may be provided on a substrate 10. The detecting part 200 may be spaced apart from the receiving part 100 in a first direction D1, which is substantially parallel to a top surface of the substrate 10. The receiving part 100 and the detecting part 200 may be connected to each other via the connecting part 300.

The substrate 10 may be a semiconductor substrate, a glass substrate, or a polymer substrate. But the inventive concept is not limited thereto, and the kind of the substrate 10 may be variously changed.

The receiving part 100 may include a transition metal dichalcogenide layer 110, a charge inducing layer 120, and a charge inducing electrode 130.

The transition metal dichalcogenide layer 110 may be provided on the substrate 10. The transition metal dichalcogenide layer 110 may include at least one of transition metal dichalcogenides. The transition metal dichalcogenides may be a metal compound, which may be represented by a chemical formula MX₂. In the chemical formula, M may be a transition metal element (e.g., tungsten (W), molybdenum (Mo), or zirconium (Zr)), and X may be a chalcogen element (e.g., sulfur (S), selenium (Se), or tellurium (Te)). For example, the transition metal dichalcogenide layer 110 may be formed of or include WSe₂, MoS₂, WS₂, MoSe₂, MoTe₂, WTe₂, ZrS₂, or ZrSe₂.

The charge inducing layer 120 may be provided on the transition metal dichalcogenide layer 110. For example, the charge inducing layer 120 may be provided to cover a top surface of the transition metal dichalcogenide layer 110. The charge inducing layer 120 may include a conductive material and may be configured to allow an incident light to pass therethrough. In some embodiments, the charge inducing layer 120 may be provided in the form of ionic gel. For example, the charge inducing layer 120 may include N,N-diethyl-N-(2-methoxyethyl)-N-methylammonium bis(trifluoromethylsulfonyl)imide (DEME-TFSI), LiClO₄, or 1-ethyl-3-methylimidazolium bis(trifluoromethylsulfonyl)imide (EMIM-TFSI).

The charge inducing electrode 130 may be provided to be spaced apart from the transition metal dichalcogenide layer 110 and may be electrically connected to the charge inducing layer 120. For example, the charge inducing electrode 130 may be spaced apart from the transition metal dichalcogenide layer 110 in the first direction D1. In some embodiments, as shown in FIG. 1, the charge inducing electrode 130 may be provided on the substrate 10, and the charge inducing layer 120 may be provided to cover the charge inducing electrode 130. But the inventive concept is not limited thereto.

A voltage may be applied to the charge inducing layer 120 through the charge inducing electrode 130, and in this case, a vertical electric field may be produced on the transition metal dichalcogenide layer 110 (e.g., in an about 5 nm thick region from a top surface of the transition metal dichalcogenide layer 110). Furthermore, the electric field may be used to control a charge state of an upper region of the transition metal dichalcogenide layer 110. For example, if a positive voltage is applied to the charge inducing layer 120 through the charge inducing electrode 130, an electric field may be applied in the upper region of the transition metal dichalcogenide layer 110, and electrons may gather in the upper region of the transition dichalcogenide layer 110. Accordingly, a two-dimensional electron gas (2DEG) may be formed in the upper region of the transition metal dichalcogenide layer 110.

Due to the electric field applied to the upper region of the transition metal dichalcogenide layer 110 and the 2DEG formed in the upper region of the transition metal dichalcogenide layer 110, inversion symmetry of the upper region of the transition metal dichalcogenide layer 110 may be broken, and a Rashba-type spin splitting may occur in the upper region of the transition metal dichalcogenide layer 110.

When the Rashba-type spin splitting occurs, an electron in the upper region of the transition metal dichalcogenide layer 110 may have a spin that is parallel to an in-plane direction (e.g., substantially parallel to the top surface of the transition metal dichalcogenide layer 110). In addition, when the Rashba-type spin splitting occurs, a spin state and a valley state of an electron in the upper region of the transition metal dichalcogenide layer 110 may be strongly coupled to each other. In other words, electrons in opposite valleys may have spins of opposite directions.

If, when the Rashba-type spin splitting occurs, a circularly polarized light is incident into the upper region of the transition metal dichalcogenide layer 110 from the outside, valley-spin photoelectrons may be generated in the transition metal dichalcogenide layer 110. A valley state (or valley information) and a spin state spin information) of the valley-spin photoelectron may be strongly coupled to each other.

A valley state and a spin state of the valley-spin photoelectron may be changed depending on an incidence direction of a circularly polarized light and/or a polarization type of the circularly polarized light (i.e., depending on whether the circularly polarized light is right- or left-handed). In the case where the circularly polarized light has the same incidence direction, valley-spin photoelectrons, which are respectively generated by right- and left-handed circularly polarized light, may be in opposite valleys and may have spins of opposite directions.

A circularly polarized light for generating valley-spin photoelectrons may be incident at an angle to the top surface of the transition metal dichalcogenide layer 110. For example, the circularly polarized light may have an incident angle that is greater than 0° and is less than 90°. An incident angle of the circularly polarized light may be defined as an angle between the circularly polarized light and a third direction D3, which is perpendicular to the top surface of the transition metal dichalcogenide layer 110. In some embodiments, the incident angle of the circularly polarized light may be about 45°.

When viewed in a plan view, the circularly polarized light may be incident to the transition metal dichalcogenide layer 110 in a direction that is substantially parallel or anti-parallel to the first direction D1. In other words, an orthogonal projection of the circularly polarized light onto the top surface of the transition metal dichalcogenide layer 110 may be substantially parallel or antiparallel to the first direction D1. Valley-spin photoelectrons, which are produced by such circularly polarized light, may have a spin that is substantially parallel or antiparallel to the first direction D1.

In the case where, in a plan view, the circularly polarized light is incident in a direction substantially parallel to the first direction D1, spins of valley-spin photoelectrons may vary depending on the kind of the circularly polarized light. As an example, in the case where a left-handed circularly polarized light is incident into the transition metal dichalcogenide layer 110, valley-spin photoelectrons whose spins are substantially parallel to the first direction D1 may be generated. As another example, in the case where a right-handed circularly polarized light is incident into the transition metal dichalcogenide layer 110, valley-spin photoelectrons whose spins are substantially antiparallel to the first direction D1 may be generated.

Similarly, in the case where, in a plan view, the circularly polarized light is incident in a direction substantially antiparallel to the first direction D1, spins of valley-spin photoelectrons may vary depending on the kind of the circularly polarized light. As an example, in the case where a left-handed circularly polarized light is incident into the transition metal dichalcogenide layer 110, valley-spin photoelectrons whose spins are substantially antiparallel to the first direction D1 may be generated. As another example, in the case where a right-handed circularly polarized light is incident into the transition metal dichalcogenide layer 110, valley-spin photoelectrons whose spins are substantially parallel to the first direction D1 may be generated.

In some embodiments, as shown in FIG. 1, the receiving part 100 may further include observation electrodes 140. The observation electrodes 140 may be provided on the transition metal dichalcogenide layer 110 and may be spaced apart from each other in a second direction D2, which is substantially parallel to the top surface of the substrate 10 and intersects with (e.g., perpendicular to) the first direction D1. The observation electrodes 140 may be used to examine whether or not the valley-spin photoelectrons are generated and what characteristics the valley-spin photoelectrons have. But the inventive concept is not limited thereto, and in certain embodiments, the observation electrodes 140 may not be provided.

The detecting part 200 may include a topological insulating layer 210 and first and second detection electrodes 220 and 222.

The topological insulating layer 210 may be provided on the substrate 10 and may be spaced apart from the transition metal dichalcogenide layer 110 in the first direction D1. The topological insulating layer 210 may include a topological insulator.

The topological insulator may be a compound that can be represent by a chemical formula A_{X}B_{Y}C_{Z}D_{W}, where 0<X≤10, 0<Y≤10, 0<Z≤10, and 0<W≤10. Here, each of A and B may be Bi, Sb, Tl, Pb, Sn, In, Ga, or Ge, and each of C and D may be Se, Te, or S. As an example, the topological insulator may be a compound that can be represent by a chemical formula A_{1-X}B_{X}C_{1-Y}D_{Y} (0<X≤1 and 0<Y≤1), A_{2-X}B_{X}C_{3-Y}D_{Y} (0<X≤2 and 0<Y≤3), A_{3-X}B_{X}C_{4-Y}D_{Y} (0<X≤3 and 0<Y≤4), or A_{5-X}B_{X}C_{7-Y}D_{Y} (0<X≤5 and 0<Y≤7). Here, each of A and B may be Bi, Sb, Tl, Pb, Sn, In, Ga, or Ge, and each of C and D may be Se, Te, or S. As another example, the topological insulator may be one of Bi₂Se₃, Bi₂Te₃, Ge₂Se₂Te₅, Sb₂Te₃, Sb₂Se₃, Bi₂Te₂Se, Bi₂Te_{1.6}S_{1.4}, Bi_{1.1}Sb_{0.9}Te₂S, Bi_{1.5}Sb_{0.5}Te_{1.7}Se_{1.3}, TlBiSe₂, TlBiTe₂, TlBi(S₁₋ₓSeₓ)₂, PbBi₂Te₄, PbSb₂Te₄, GeBi₂Te₄, or PbBi₄Te₇.

The first and second detection electrodes 220 and 222 may be provided on the topological insulating layer 210. The first and second detection electrodes 220 and 222 may be spaced apart from each other in the second direction D2. When viewed in the first direction D1, the first detection electrode 220 may be located on a left top surface of the topological insulating layer 210 and the second detection electrode 222 may be located on a right top surface of the topological insulating layer 210.

The connecting part 300 may be provided to electrically connect the transition metal dichalcogenide layer 110 to the topological insulating layer 210. A portion of the connecting part 300 may be provided on the top surface of the transition metal dichalcogenide layer 110, and an opposite portion of the connecting part 300 may be provided on the top surface of the topological insulating layer 210.

The connecting part 300 may include a material having a long spin diffusion length and a one- or two-dimensional structure. The spin diffusion length may be an average value of lengths which allow an electron to be diffused without a substantial change in its original spin state. For example, the connecting part 300 may include graphene, a carbon nanotube, or a silicon membrane.

Valley-spin photoelectrons, which are generated in the transition metal dichalcogenide layer 110, may be transported to the top surface of the topological insulating layer 210 through the connecting part 300, without a substantial change in their spin and valley states. The valley-spin photoelectrons may be transported through diffusion.

The top surface of the topological insulating layer 210 may have a spin-momentum locking property. On the top surface of the topological insulating layer 210, an electron may have momentum that is fixed in a direction perpendicular to its spin direction. For example, on the top surface of the topological insulating layer 210, the momentum of the electron may be fixed in a direction that is rotated in a counterclockwise direction by 90° from its spin direction.

Accordingly, the valley-spin photoelectrons, which are transported to the top surface of the topological insulating layer 210, may be transported to the first detection electrode 220 or the second detection electrode 222, depending on a spin state thereof. As an example, valley-spin photoelectrons, whose spins are substantially parallel to the first direction D1, may be transported to the first detection electrode 220. As another example, valley-spin photoelectrons, whose spins are substantially antiparallel to the first direction D1, may be transported to the second detection electrode 222. The valley-spin photoelectrons may be detected through an external detection circuit (not shown), which is electrically connected to the first and second detection electrodes 220 and 222.

As stated above, according to some embodiments of the inventive concept, a photoelectric device may be configured to receive a circularly polarized light and produce an electric signal therefrom. In addition, a direction of the electric signal may be changed depending on the kind of a circularly polarized light to be incident thereto.

In a conventional photoelectric device, production of an electric signal may be only determined by whether there is an incident light. By contrast, a photoelectric device according to some embodiments of the inventive concept may be configured to examine whether there is an incident light or to examine what polarization type the incident light has (i.e., whether the circularly polarized light is right- or left-handed) and to produce an electric signal based on the examination result. The photoelectric device according to some embodiments of the inventive concept may be used to realize a next-generation optical communication technology.

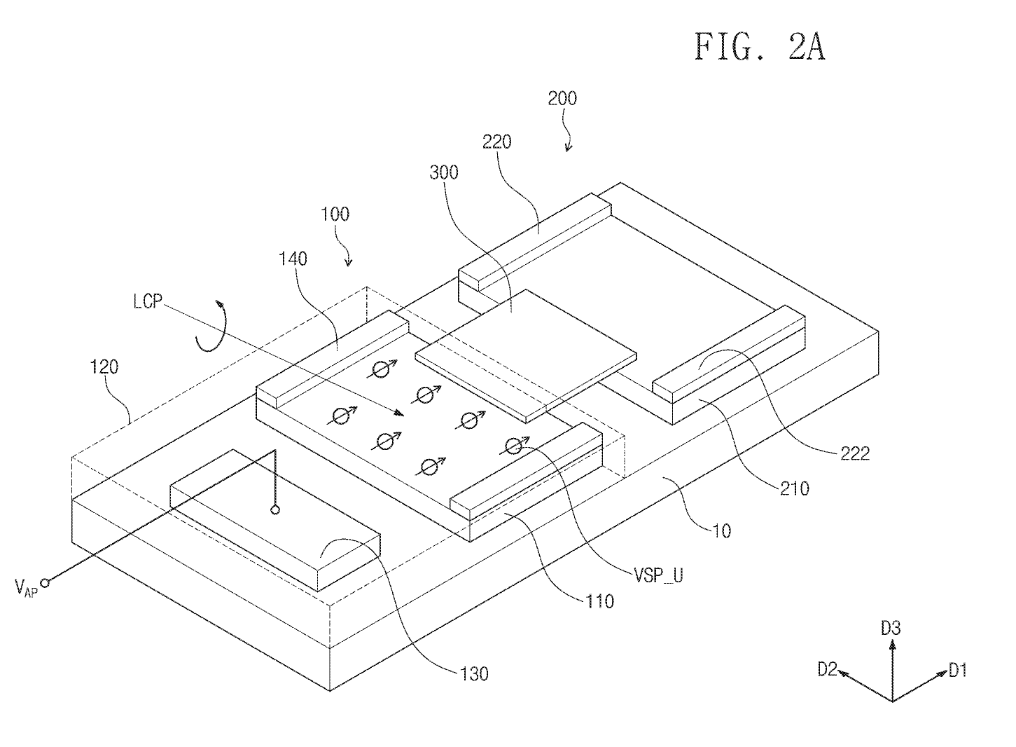

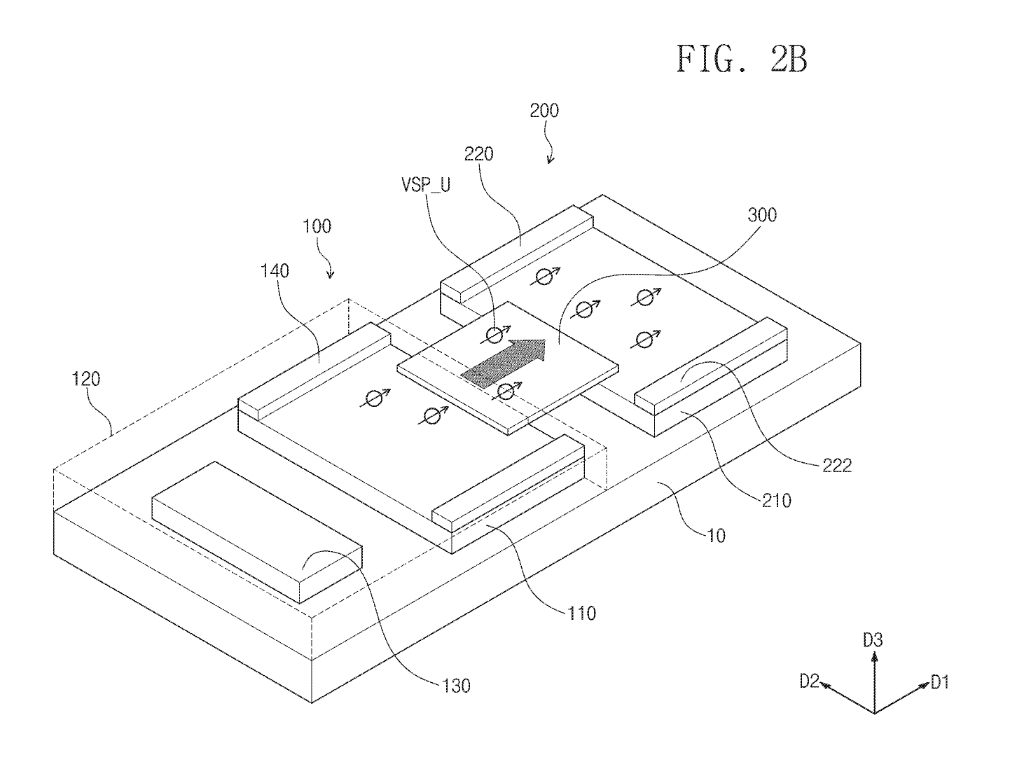

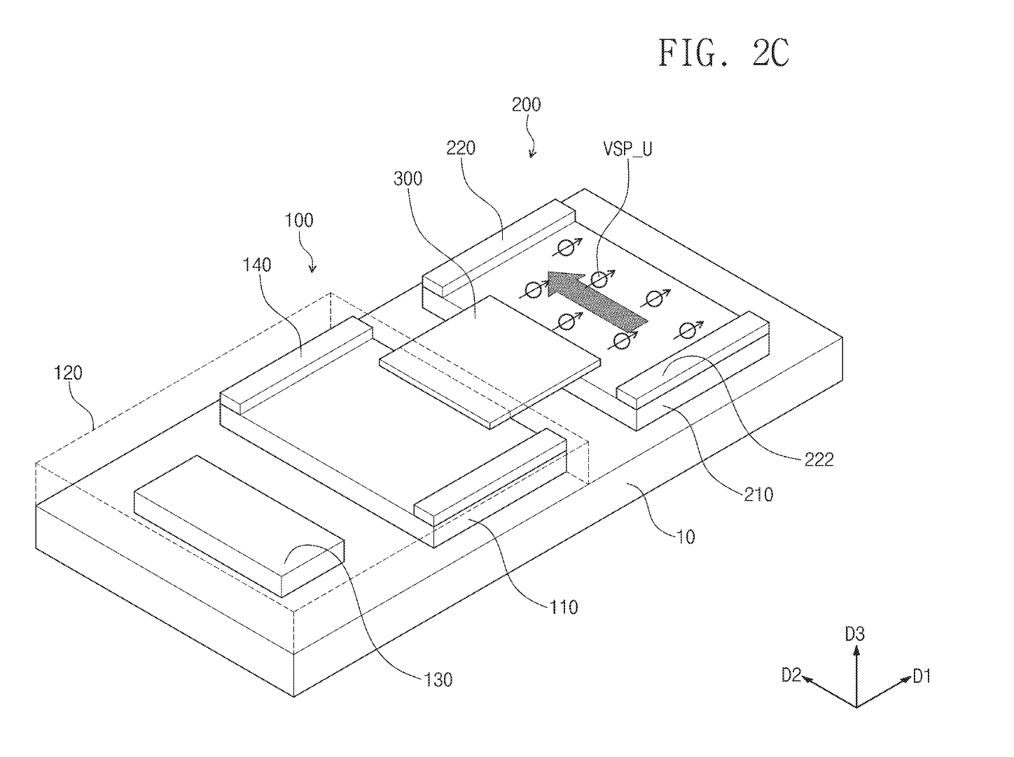

FIGS. 2A to 2C are perspective views illustrating an operation of a photoelectric device according to some embodiments of the inventive concept. In detail, FIGS. 2A to 2C are perspective views illustrating an operation of a photoelectric device, when a left-handed circularly polarized light is incident into a transition metal dichalcogenide layer of the photoelectric device. For concise description, an element previously described with reference to FIG. 1 may be identified by the same reference number, and an overlapping description thereof may not be repeated.

Referring to FIG. 2A, an electric field may be produced in an upper region of the transition metal dichalcogenide layer 110. The electric field in the upper region of the transition metal dichalcogenide layer 110 may be produced by applying a voltage V_{AP} to the charge inducing electrode 130. Accordingly, in the upper region of the transition metal dichalcogenide layer 110, a 2DEG may be formed and a Rashba-type spin splitting may occur.

A left-handed circularly polarized light LCP may be incident into the transition metal dichalcogenide layer 110 from the outside, when the electric field is produced in the upper region of the transition metal dichalcogenide layer 110. The left-handed circularly polarized light LCP may be incident at an angle to the top surface of the transition metal dichalcogenide layer 110 (e.g., at an incident angle of about 45°). When viewed in a plan view, the left-handed circularly polarized light LCP may have an incidence angle that is substantially parallel to the first direction D1. Accordingly, valley-spin photoelectrons VSP_U, whose spins are substantially parallel to the first direction D1, may be generated in the upper region of the transition metal dichalcogenide layer 110.

Referring to FIG. 2B, the valley-spin photoelectrons VSP_U may be transported to the top surface of the topological insulating layer 210 through the connecting part 300. The spin and valley states of the valley-spin photoelectrons VSP_U may be preserved, during the transport of the valley-spin photoelectrons VSP_U. Accordingly, the valley-spin photoelectrons VSP_U, which are transported to the top surface of the topological insulating layer 210, may have spins that are substantially parallel to the first direction D1.

Referring to FIG. 2C, owing to the spin-momentum locking property of the top surface of the topological insulating layer 210, the valley-spin photoelectrons VSP_U may be transported to the first detection electrode 220. Such valley-spin photoelectrons VSP_U may be detected through an external detection circuit (not shown), which is electrically connected to the first and second detection electrodes 220 and 222.

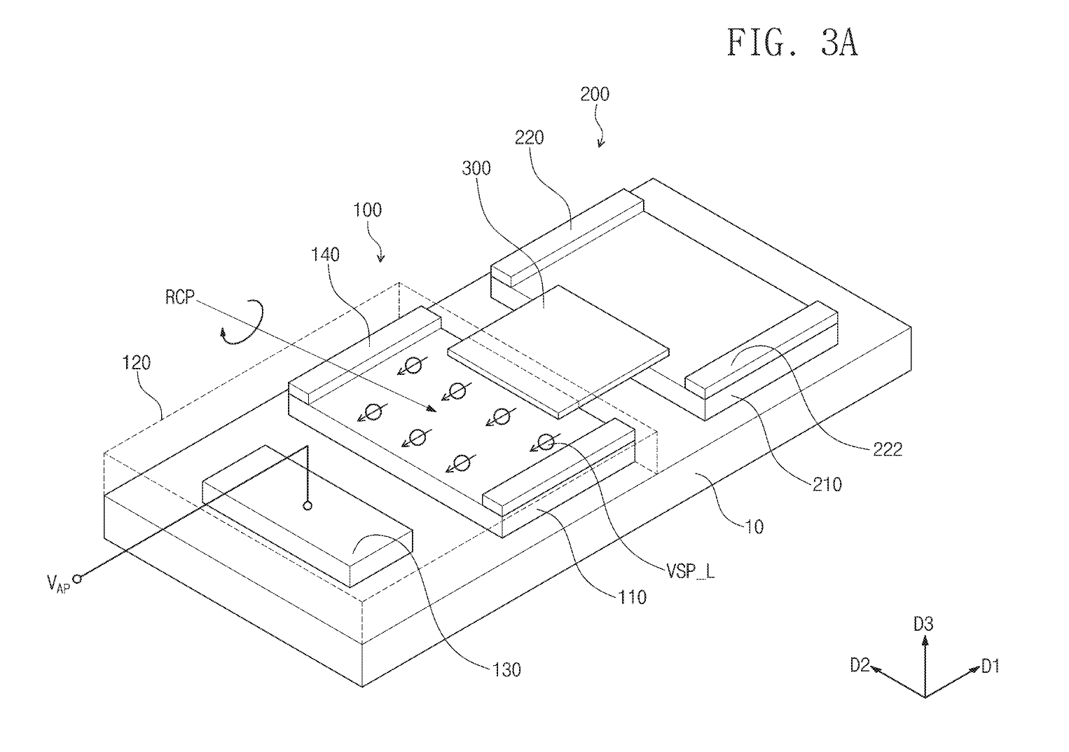

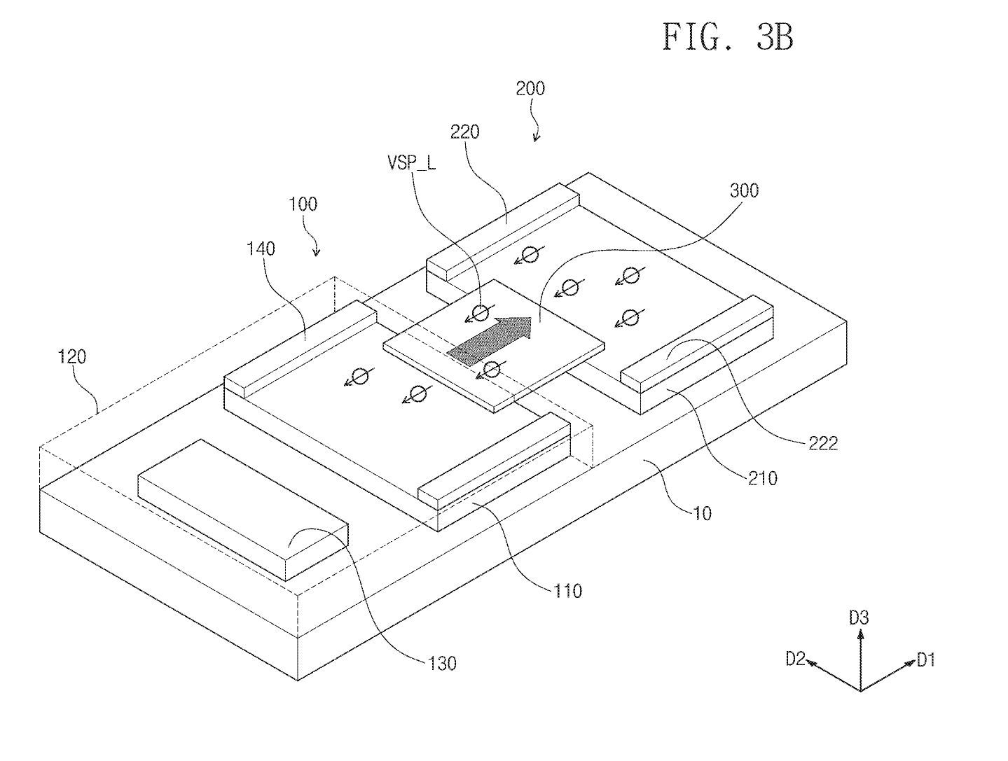

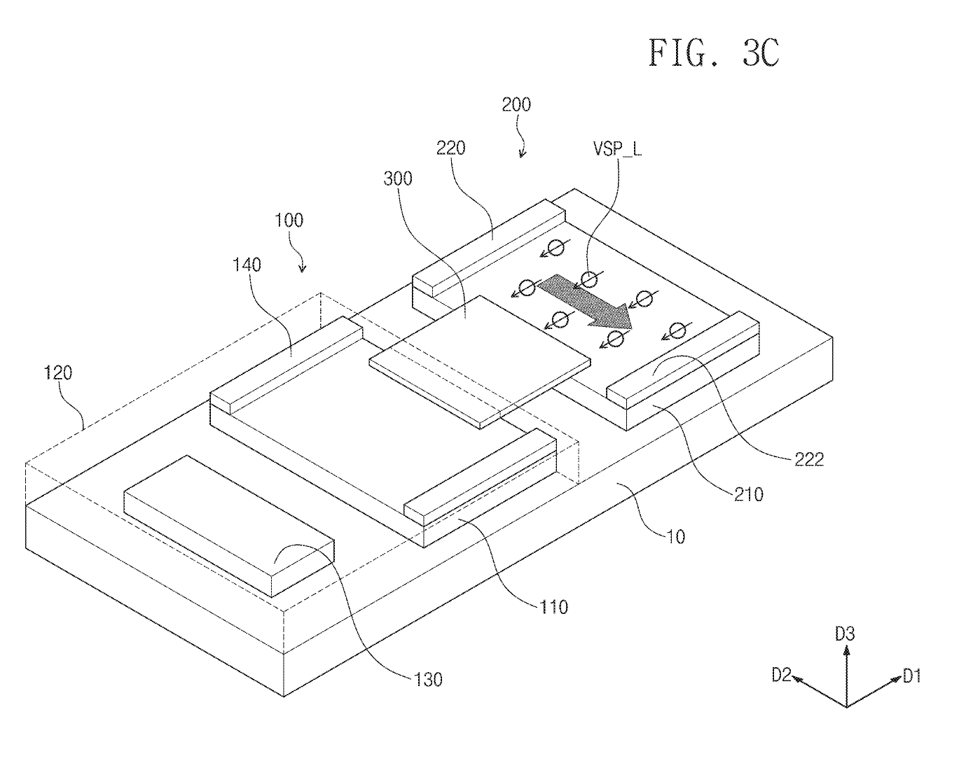

FIGS. 3A to 3C are perspective views illustrating an operation of a photoelectric device according to some embodiments of the inventive concept. In detail, FIGS. 3A to 3C are perspective views illustrating an operation of a photoelectric device, when a right-handed circularly polarized light is incident into a transition metal dichalcogenide layer of the photoelectric device. For concise description, an element previously described with reference to FIG. 1 may be identified by the same reference number, and an overlapping description thereof may not be repeated.

Referring to FIG. 3A, an electric field may be produced in an upper region of the transition metal dichalcogenide layer. The electric field in the upper region of the transition metal dichalcogenide layer 110 may be produced by applying a voltage V_{AP} to the charge inducing electrode 130. Accordingly, in the upper region of the transition metal dichalcogenide layer 110, a 2DEG may be formed and a Rashba-type spin splitting may occur.

A right-handed circularly polarized light RCP may be incident into the transition metal dichalcogenide layer 110 from the outside, when the electric field is produced in the upper region of the transition metal dichalcogenide layer 110. The right-handed circularly polarized light RCP may be incident at an angle to the top surface of the transition metal dichalcogenide layer 110 (e.g., at an incident angle of about 45°). When viewed in a plan view, the right-handed circularly polarized light RCP may have an incidence angle that is substantially parallel to the first direction D1. Accordingly, valley-spin photoelectrons VSP_L, whose spins are substantially antiparallel to the first direction D1, may be generated in the upper region of the transition metal dichalcogenide layer 110.

Referring to FIG. 3B, the valley-spin photoelectrons VSP_L may be transported to the top surface of the topological insulating layer 210 through the connecting part 300. The spin and valley states of the valley-spin photoelectrons VSP_L may be preserved, during the transport of the valley-spin photoelectrons VSP_L. Accordingly, the valley-spin photoelectrons VSP_L, which are transported to the top surface of the topological insulating layer 210, may have spins that are substantially antiparallel to the first direction D1.

Referring to FIG. 3C, owing to the spin-momentum locking property of the top surface of the topological insulating layer 210, the valley-spin photoelectrons VSP_L may be transported to the second detection electrode 222. The valley-spin photoelectrons VSP_L may be detected through an external detection circuit (not shown), which is electrically connected to the first and second detection electrodes 220 and 222.

According to some embodiments of the inventive concept, a photoelectric device may be configured to receive a circularly polarized light and produce an electric signal therefrom. In addition, a direction of the electric signal may be changed depending on the kind of a circularly polarized light to be incident thereto.

While example embodiments of the inventive concept have been particularly shown and described, it will be understood by one of ordinary skill in the art that variations in form and detail may be made therein without departing from the spirit and scope of the attached claims.

What is claimed is:

1. A photoelectric device, comprising:
a receiving part including a transition metal dichalcogenide layer and a charge inducing layer, the charge inducing layer covering the transition metal dichalcogenide layer;
a detecting part including a topological insulating layer spaced apart from the transition metal dichalcogenide layer; and
a connecting part connecting the transition metal dichalcogenide layer to the topological insulating layer.

2. The device of claim 1, wherein the detecting part further comprises first and second detection electrodes provided on the topological insulating layer.

3. The device of claim 2, wherein the transition metal dichalcogenide layer and the topological insulating layer are spaced apart from each other in a first direction, and
the first and second detection electrodes are spaced apart from each other in a second direction intersecting the first direction.

4. The device of claim 1, wherein the connecting part comprises two portions, one of which is provided on a top surface of the transition metal dichalcogenide layer, and another of which is provided on a top surface of the topological insulating layer.

5. The device of claim 1, wherein the connecting part comprises graphene, a carbon nanotube, or a silicon membrane.

6. The device of claim 1, wherein the charge inducing layer is provided in the form of ionic gel.

7. The device of claim 1, further comprising a charge inducing electrode electrically connected to the charge inducing layer.

8. The device of claim 1, wherein the transition metal dichalcogenide layer includes transition metal dichalcogenide, and
the topological insulating layer includes a topological insulator.

9. A photoelectric device, comprising:
a transition metal dichalcogenide layer;
a charge inducing layer configured to apply an electric field to an upper region of the transition metal dichalcogenide layer;
a topological insulating layer spaced apart from the transition metal dichalcogenide layer; and
a connecting part connecting the transition metal dichalcogenide layer to the topological insulating layer.

10. The device of claim 9, further comprising a charge inducing electrode electrically connected to the charge inducing layer,
wherein the electric field is applied to the upper region of the transition metal dichalcogenide layer by applying a voltage to the charge inducing electrode.

11. The device of claim 9, wherein a valley-spin photoelectron is produced in the upper region of the transition metal dichalcogenide layer, when the electric field is applied to the upper region of the transition metal dichalcogenide layer and a circularly polarized light is incident into the transition metal dichalcogenide layer.

12. The device of claim 11, wherein a valley state and a spin state of the valley-spin photoelectron are coupled to each other.

13. The device of claim 11, wherein the valley-spin photoelectron has a first spin direction, when the circularly polarized light is a left-handed circularly polarized light, and a second spin direction, when the circularly polarized light is a right-handed circularly polarized light, and
the first spin direction and the second spin direction are opposite to each other.

14. The device of claim 13, wherein the valley-spin photoelectron is transported to a top surface of the topological insulating layer through the connecting part, and
on the top surface of the topological insulating layer, the valley-spin photoelectron with the first spin direction is transported in a direction opposite to that of the valley-spin photoelectron with the second spin direction.

15. The device of claim 13, wherein the topological insulating layer is spaced apart from the transition metal dichalcogenide layer in a first direction,
the circularly polarized light is incident in a direction that is substantially parallel to the first direction, when viewed in a plan view,
the first spin direction is substantially parallel to the first direction, and
the second spin direction is substantially antiparallel to the first direction.

16. The device of claim 15, further comprising first and second detection electrodes that are provided on a top surface of the topological insulating layer,
wherein the first and second detection electrodes are spaced apart from each other in a second direction intersecting the first direction,
the valley-spin photoelectron is transported to the top surface of the topological insulating layer through the connecting part, and
on the top surface of the topological insulating layer, the valley-spin photoelectron with the first spin direction is transported toward the first detection electrode and the valley-spin photoelectron with the second spin direction is transported toward the second detection electrode.

17. The device of claim 9, wherein the electric field is used to form a two-dimensional electron gas in the upper region of the transition metal dichalcogenide layer.
